(19) United States
(12) Patent Application Publication
(10) Pub. No.: US 2006/0098451 A1
(43) Pub. Date: May 11, 2006

(54) Illuminator for video display apparatus

(75) Inventors: Chih-Lu Hsu, Kaohsiung (TW); Chun-Chang Hung, Kaohsiung (TW); Jeffrey Lee, El Sobrante, CA (US)

Correspondence Address: GENUS LAW GROUP;LOWE HAUPTMAN & BERNER, LLP, 1700 DIAGONAL ROAD, SUITE 300, ALEXANDRIA, VA, 22314, US

(73) Assignee: GLOBAL FIBEROPTICS INC.

(21) Appl. No.: 10/983,233

(22) Filed: Nov. 8, 2004

(51) Int. Cl. H01L 33/00; F21V 7/04

(52) U.S. Cl. 362/555; 362/19; 362/231; 362/559

(57) ABSTRACT

The present invention relates to an illuminator that comprises one or a plurality of light panels which further comprise highly directional solid-state lighting units, wherein the light component emitted from the highly directional solid-state lighting unit has high directivity, and a light panel comprising an array of the highly directional solid-state lighting units need no additional optical elements to collimate or condense the light emitted from the light panel. The present invention also relates to the applications thereof in video display apparatuses, rear projection televisions, printers, scanners, copy machines, and more. The present invention realizes a uniform high luminous solid-state color source and video display apparatus of compact size that exhibits high utilized efficiency of a luminous flux from the light panel source and can provide a uniform image. The present invention can be used in general lighting, automobile lighting and other display systems. Its compactness, high optical utilized efficiency, brightness and uniformity, low cost design and ability to project a still or moving picture with high color reproduction capabilities make it useful in the applications described above.

### BACKGROUND OF THE INVENTION

1. Field of the Invention

The present invention relates to an illuminator that comprise one or a plurality of light panels which further comprise highly directional solid-state lighting units, wherein the light panel comprising an array of the highly directional solid-state lighting units needs no additional optical elements to collimate or condense the light emitted from the light panel. The present invention also relates to the applications thereof in video display apparatuses, rear projection televisions, printers, scanners, copy machines, and more.

2. Description of the Related Art

A conventional projection apparatus is typically applied to a front projection lens or a large screen. Light sources such as halogen lamps and arc lamps with high luminance have to be used. Although these kinds of lamps exhibit high luminance, they have disadvantages which include high power consumption, high operating temperature, poor color gamut, UV-IR issues, volatile glass bulb construction, sizable mass and volume, longer switch time, short lifespan, higher costs, and, due to the use of mercury, and not being environmentally friendly. Therefore, these kinds of lamps are only used when high luminance is required.

Semiconductor optical elements with directional light emission such as Photonic Crystal Light Emitting Diodes (PC-LED), Laser Diodes (LD), Vertical Cavity Surface Emitting Lasers (VCSEL), and those of that sort are plausible substitutes for the light units.

A conventional LED light source uses a built in focus and diffusive optical element and is packaged with an external reflective optical element in order to achieve a collimated or focused light beam. FIG. 1 shows conventional optical packages of LEDs disclosed in U.S. Pat. No. 6,603,148 (Sano et al.). An LED element 10 is covered by a transparent and soft silicone resin 11 and a resin package 12. The section encompassing the silicone resin is a hemispheric lens 13 that projects upward. The coated reflective surface 14 reflects light emitted from the side of the LED element 10 upwards to enhance optical collective efficiency. The package has a built in coated reflective surface and a special outer lens shape that condenses light and protects the LED die. All of the contingent optical packaging occupies the vast majority of the overall volume. The built in coated reflective surface and special lens shaped structures are costly to manufacture and are difficult to align which in turn could lead to a lack of uniformity in performance from one LED to the next. Also, the luminous flux output distribution varies largely between different LEDs products.

U.S. Pat. No. 6,644,814 (Ogawa et al.) discloses a LED-Illumination type DMD projector which is illustrated in FIG. 2. The projector uses three separate LED array light sources 1G, 1B, and 1R (Not shown in FIG. 2), which individually pass green, blue and red lights through the first fly-eye lenses 2G, 2B, and 2R (Not shown in FIG. 2) respectively. The green, blue and red lights then proceed through a set of fly-eye lenses 3G, 3B, and 3R and then pass through a color combiner cross dichroic prism (DXP) 21 to form white light. The white light is then passed through illumination optics 22, 23, 24, 25, and 26, and is then modulated and reflected by the DMD panel 27. The modulated reflected light then passes through DMD illumination prisms 25 and 28 and a projection lens 29. Although the projector exerts good uniformity, it lacks compactness and is heavily weighted. Furthermore, the separation and recombination of color light beam that occurs when the color light beams emitted from the three separate LED sources pass through the DXP could result in lateral color smearing in the projection image.

U.S. Pub. No. 2004/0062044 (Hanano) discloses an illumination apparatus and image projection apparatus which utilize the illumination apparatus as shown in FIG. 3. The illumination apparatus is composed of a small-plane light source 31, a columnar light leading member 32 and an angle position converting member 33. The illumination apparatus is further composed of a light modulation element 34 and a projection lens 35. Because the small-plane light source has diffusion radiation characteristics, some of the large angle color light beam emitted from the small-plane light source would either be unable to enter the columnar light leading member or unable to exit it. The latter would be due to the color light beam's having a large incident angle and consequently reflecting repeatedly within the columnar light leading member and not being able to leave. This would result in a lowered system luminous flux output. Furthermore, because each small-plane light source must be accompanied by its own light leading member, the system becomes large in size and costly to manufacture as well as hard to align in the production line.

U.S. Pat. No. 6,517,211 (Mihara) discloses an illumination device for a projection-type display and projection-type display apparatus as shown in FIG. 4. The system is composed of three laser light sources 41G, 41B and 41R accompanied by three light guides 42G, 42B and 42R, three diffusive reflection surfaces 43G, 43B and 43R, three light integrators 44G, 44B and 44R, three convergence lenses 45G, 45B and 45R, three light valves 46G, 46B and 46R, a synthesizer prism 47 and a projection lens member 48. The three-laser projection display has limitations on the light incident angle from the laser to diffusive reflection surface, and on the light reflection angle from the diffusive reflection surface to the light integrator. Due to the limitations, some incident light with large angle cannot reach the light valve. The system is difficult to manufacture and align. In addition to it's being difficult to manufacture and align, the light guides it uses lose light. Furthermore, there should be a hole in the integrator that allows for the light transmitted from the laser to diffuse to the diffusive reflection surface. The hole can cause light loss as well as long-term reliability problems. It opens up the possibility of being a point of deterioration during long-term operation. An isolator should be disposed between the laser source and the diffusive reflection surface in order to prevent light feedback problem. This would result in higher costs and increased difficulty in manufacturing the display apparatus.

U.S. Pat. No. 6,547,421 (Sugano) discloses a display apparatus as shown in FIG. 5. The green illuminating optical system 51G directs green light emitted from the green light source to the light valve 52G and then passes the green light through the cubic dichroic prism 53 to reach the projection lens 54. The red and blue lights pass through the system in same manner as that of the green light. The cubic dichroic prism combines the green, red and blue light and propagates the resulting light onto the projection lens.

In the conventional display apparatus, since there are many optical lenses such as coupling lenses, two fly-eye lenses and three condenser lenses used between light source and light valve, the optical system is costly and large. It is difficult to realize a feasibly compact apparatus. Furthermore, the luminous flux emitted from the plurality of light sources passes through so many optical lenses that utilized efficiency and system brightness is decreased.

U.S. Pat. No. 6,648,475 (Roddy et al.) discloses a method and apparatus for increasing color gamut of a display as shown in FIG. 6. A p-polarized green light emitted from the green light source 61G passes through an uniformizing optics 62G, a telecentric condenser lens 63G, a dichroic mirror 64, a polarization beam-splitter 65G and strikes a reflective spatial light modulator 66G(R-SLM). The modulated s-polarized green light is reflected by the R-SLM, becomes incident to the polarization beam-splitter 65G, and is then reflected to an X-cube 67, a projection lens 68 and finally to a display surface 60. The blue-green, red and blue lights pass through the system in same manner as green light. The X-cube combines modulated green, blue-green, red and blue lights and finally sent the combined lights to a projection lens.

The conventional apparatus offers a four separate color light source solution to expanding color gamut in different optical paths. The use of myriad optical components results in a costly and complicated display system. This results in a large system size. Moreover, the use of numerous optical components increases optical path which lowers utilized efficiency and system brightness. Longer optical path also create difficulties in adjusting the four optical paths to reach a balanced color performance. As a result, some lateral color smearing appears on the display surface.

In summary, there is a desire to increase the durability, luminous flux, and practicality of light sources. Increasing system brightness, uniformity and optical utilized efficiency, lowering manufacturing costs and power consumption, expanding color gamut and dynamic color control, and realizing compact vivid video display apparatuses are all fields that can be improved upon.

### SUMMARY OF THE INVENTION

The primary object of the present invention is to provide an illuminator or a light module that comprises one or a plurality of light panels which further comprise at least one highly directional solid-state lighting unit, wherein the light emitted from the solid-state lighting unit has high directivity and has its own color. Arrays of the solid-state lighting units are packaged on the same or different light panels.

Another objective of the present invention is to provide apparatuses for employing the light panel or illuminator according to the present invention in a video display apparatus.

The primary characteristic of the present invention is to utilize a highly directional solid-state lighting unit as the light source, wherein the aforementioned solid-state lighting unit has a beam divergence solid angle of less than 15 degrees in contrast to a traditional LED chip that has a light output with diffusion radiation characteristics, in order that the light panel which comprises at least one aforementioned lighting unit can offer a directional light output.

Another characteristic of the present invention is that there is no focus, diffusive optical elements, and/or any kind of external reflection to optical elements, which are utilized to collimate or condense the light emitted from the solid-state lighting unit, between each solid-state lighting unit and a protective transparent cover window of the light panel.

Yet another characteristic of the present invention is that the array of the highly directional solid-state lighting unit can mount directly onto the light panel without the use of any built in focus, diffusive optical elements, and/or any kind of external reflection optical elements, which are utilized to collimate or condense the light emitted from the light panel since each light component itself emitted from the highly directional solid-state lighting unit has high directivity.

Still another characteristic of the present invention is that as fewer optical components are used in apparatuses according to the present invention, and those apparatuses are compact in size and light in weight, and the manufacturing cost also can be reduced.

Further another characteristic of the present invention is that the present invention can decrease the optical path so that the efficiency and brightness of the system can be increased, and the power consumption also can be reduced, and additionally the problems of color balance and lateral color smear appearing on the display surface can be avoided.

The light panel itself of the present invention comprises highly directional solid-state lighting units with one or more colors. The different color solid-state lighting units of high directivity are mixed and arranged on the light panel. Multiple color light panels can be dynamically controlled via an electrical circuit to offer a wide variety of colors.

According to one aspect of the present invention, a light module, which functions as a uniform and highly luminous solid-state light source, comprises:
at least one light panel, wherein each light panel further includes one or a plurality of solid-state lighting units which are arranged and packaged in the light panel; and
at least one optical element, used to combine the optical outputs of the light panels to one optical output;
   and is characterized in that the light beam emitted from each said solid-state lighting unit of each said light panel is distributed primarily within a small solid angle less than 15 degrees, and there is no collimating or condensing optical elements existing before each said solid-state lighting unit between each solid-state lighting unit and a protective transparent cover window of the light panel.

According to one aspect of the present invention, an illuminator, which functions as a uniform and highly luminous solid-state light source, comprises:
at least one light panel, wherein each light panel further includes one or a plurality of solid-state lighting units which are arranged and packaged in the light panel; and
an integrator, disposed in front of the light output of the light panel to uniformize the spatial and angular distribution of the light beam emitted from the light panel;
   and is characterized in that the light beam emitted from the solid-state lighting unit of each light panel is distributed primarily within a small solid angle less than 15 degrees, and there is no collimating or condensing optical elements existing before each said solid-state lighting unit between each solid-state lighting unit and a protective transparent cover window of the light panel, and that there is no collimating or condensing optical elements existing between the light panel and the integrator.

According to one aspect of the present invention, there are multiple ways to arrange the highly directional solid-state lighting units on the light panel of the present invention, such as an orderly rectangular placement or an off-set placement.

According to one aspect of the present invention, the surface of the light panel can be either curved or flat.

According to one aspect of the present invention, the shape of the light panel is not limited to that of being a rectangular shape, and can resemble various shapes including circle, triangle and so forth.

According to one aspect of the present invention, the light panel of the light module or the illuminator comprises a first, second and third principal color solid-state lighting unit, wherein the first, second and third color is red, green and blue.

According to one aspect of the present invention, in addition to the first, second and third color mentioned above, the light panel of the light module or the illuminator comprises an additional fourth, fifth, sixth or more than sixth principal color solid-state lighting unit, wherein the additional fourth, fifth, sixth principal color is yellow, cyan-green, cyan-blue, in order to form a four, five, six or more than six principal color light source and expand color gamut.

According to one aspect of the present invention, the light module or the illuminator can comprise more than one light panel.

The present invention provides apparatuses for employing the light module or the illuminator of the present invention in a video display apparatus.

According to one aspect of the present invention, a video display apparatus comprises:
at least one light source, providing a uniform un-polarized or polarized single or multiple color light beams and emitting at least three color light beams including a first, second and third color light beams, wherein each of the light sources further includes an illuminator which still further comprises: at least a light panel, comprising at least a highly directive solid-state lighting unit arranged and packaged on the light panel and an integrator, disposed in front of light output of the light panel to uniformize the spatial and angular distribution of the light beam emitted from the light panel;
a color optics group, disposed at outlet of the light illuminator, and further including mirrors and lenses;
a projection lens, disposed in front of the color optics group; and
at least one spatial light modulator (SPM), disposed between the color optics group and the projection lens;
   and is characterized in that the light beam emitted from each solid-state lighting unit of each light panel of the light module is distributed primarily within a small solid angle less than 15 degrees, and there is no collimating or condensing optical elements existing before each said solid-state lighting unit between each solid-state lighting unit and a protective transparent cover window of the light panel, and that there is no collimating or condensing optical elements existing between said light panel and said integrator.

The video display apparatus of the present invention provides good color purity and expansive color gamut as well as exerts high optical uniformity, high utilized efficiency, and high system brightness. On top of that, the present invention realizes all of the above through a compact and economical vivid video display apparatus.

According to one embodiment of the present invention, the video display apparatus of the present invention can further includes an illuminating lens at the outlet of the integrator. The color light beam emitted from the light panel enters the integrator and is uniformized by the integrator. It then passes through the illuminating lens that modifies the angle and shape of the light beam, and is directed onto the spatial light modulator where it is modulated, and then passes through the projection lens.

A single optical path embodiment of the video display apparatus of the present invention includes at least a light panel, an integrator, an illuminating lens, a spatial light modulator (SLM), and a projection lens.

In a multiple optical path embodiment of the video display apparatus of the present invention, an SLM used in the above single optical path embodiment can be replaced by two or three SLMs, and can be accompanied by some optical lenses and mirrors for the purpose of separating, directing, transmitting, converting, dividing or recombining different color light beam. The optical lenses and mirrors collectively form a kind of color optics group that modulates color light beam from the integrator and transmits it onto the projection lens.

Since light emitted from the light panel of the illuminator of the present invention irradiates upon the SLM uniformly, the total light output of the video display apparatus can be increased by augmenting the electric current or by increasing the number of solid-state lighting units on the light panel. Consequently, the optical efficacy and system brightness can be efficiently enhanced.

Two or more aforementioned illuminator can be applied to the video display apparatus of the present invention, which too would result in increased brightness.

In contrast to the conventional video display apparatus, the video display apparatus of the present invention does not utilize any optical lenses or elements, which collimate or condense the light emitted from the light panel, between the light panel and the integrator.

Furthermore, the sparse use of optical components in the video display apparatus of the present invention enables it to cost less than the conventional video display apparatus. Consequent to its using few optical components, the apparatus of the present invention is compact in size and light in weight.

In the apparatus of the present invention, the vivid and sharp color video image can be realized through a dynamic switch on/off the solid-state lighting units synchronized with a video signal from the SLM and an input video signal source such as a personal computer, video gaming system, laptop or any other input signal source. The full true colors, white color balance and color temperature can also be modified and controlled dynamically.

Even though the total size of the light panel of the present invention is quite small, the light panel offers a high luminous output. Enhancing the total luminous output is easily achieved by increasing electric current or by adding more solid-state lighting units on the light panel.

This invention also provides an apparatuses for employing the illuminator of the present invention in a printer, scanner or copy machine. Furthermore, the uniform light can also be directed to an acousto-optical modulator (AOM) or an electro-optical modulator (EOM) in applications that see fast switch circumstances such as in chemical, physical, and biological studies, fiber communications, 3D displays, high resolution microscopy, spectrometers and similar applications.

### BRIEF DESCRIPTION OF THE DRAWINGS

FIG. 1 is a cross-sectional view of a conventional packaged LED component.

FIG. 2 is a conventional projection diagram wherein a cross section of an optical system at its 45-degree-inclined plane against a horizontal plane is projected on the horizontal plane.

FIG. 3 is a view showing a structure of a conventional illumination apparatus and video display apparatus.

FIG. 4 is a structural view showing a conventional projection-type display apparatus.

FIG. 5 is a schematic view showing a conventional video display apparatus of the projection type.

FIG. 6 is a schematic block diagram showing a conventional four-color projection system using four separate laser sources and four spatial light modulators.

FIG. 7-A is a schematic top view showing an orderly rectangular placement of a light panel according to one aspect of the present invention.

FIG. 7-B is a schematic top view showing an off-set arrangement of a light panel according to one aspect of the present invention.

FIG. 7-C is a schematic side view of a light panel and a protective window according to one aspect of the present invention.

FIG. 7-D is a schematic side view showing the divergence angle of a single solid-state lighting unit and a protective window according to one aspect of the present invention.

FIG. 8 is a schematic view showing one illuminator according to one aspect of the present invention.

FIG. 9-A is a schematic view showing an integrator and the light module 91 comprising two light panels and a dichroic mirror according to one embodiment of the present invention.

FIG. 9-B is a schematic view showing an integrator and the light module 92 comprising three light panels and an X-cube prism according to one embodiment of the present invention.

FIG. 9-C is a schematic view showing an integrator and the light module 93 comprising three light panels and two dichroic mirrors according to one embodiment of the present invention.

FIG. 9-D is a schematic view showing an integrator and the light module 94 comprising one light panel and a reflection mirror according to one embodiment of the present invention.

FIG. 9-E is a schematic view showing an integrator and the light module 95 comprising three light panels and two dichroic mirrors according to one embodiment of the present invention.

FIG. 9-F is a schematic view showing an integrator and the light module 96 comprising three light panels and two dichroic mirrors according to one embodiment of the present invention.

FIG. 9-G is a schematic view showing an integrator and the light module 97 comprising three light panels, two dichroic mirrors and a reflection mirror according to one embodiment of the present invention.

FIG. 10 is a schematic view showing a portion of an R-SLM based video display apparatus suitable for a DMD-based or a GLV-based video display apparatus according to one embodiment of the present invention.

FIG. 11 is a schematic view showing a portion of a printer, a scanner or a copy machine including one illuminator of the present invention.

FIG. 12 shows the color gamut of a three principal color wavelength solid-state lighting source and compares it to the color gamut of NTSC, CRT TV, a conventional data projector and a video projector.

FIG. 13 shows the color gamut of a six principal color wavelength solid-state lighting source and compares it to the color gamut of NTSC, CRT TV, a conventional data projector and a video projector.

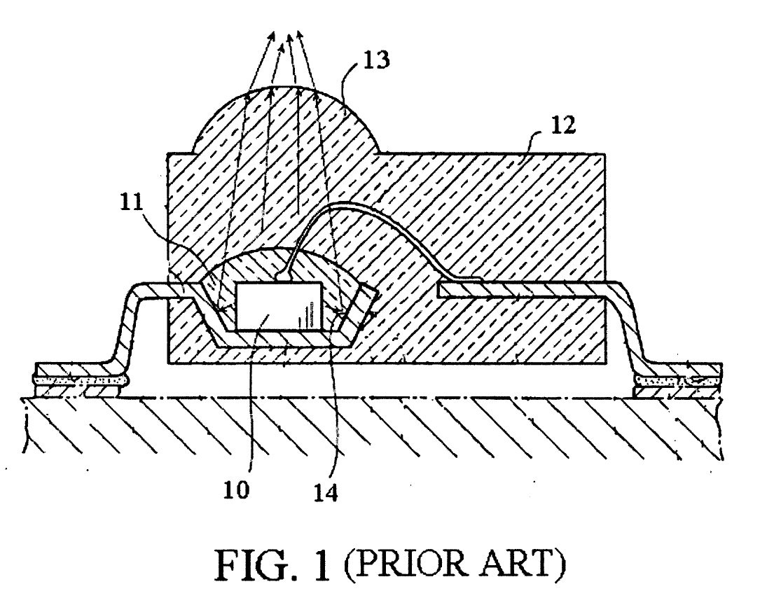

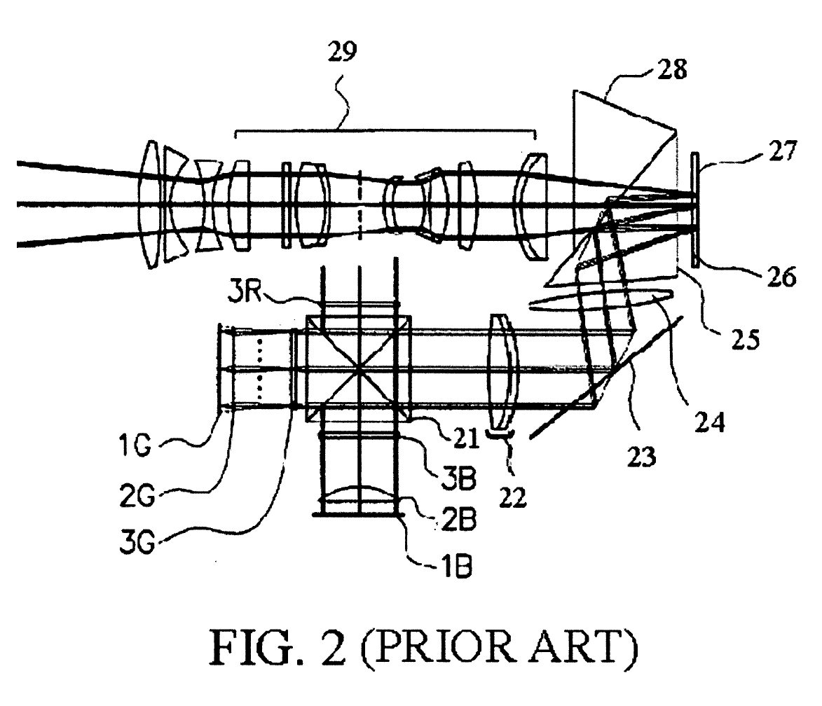

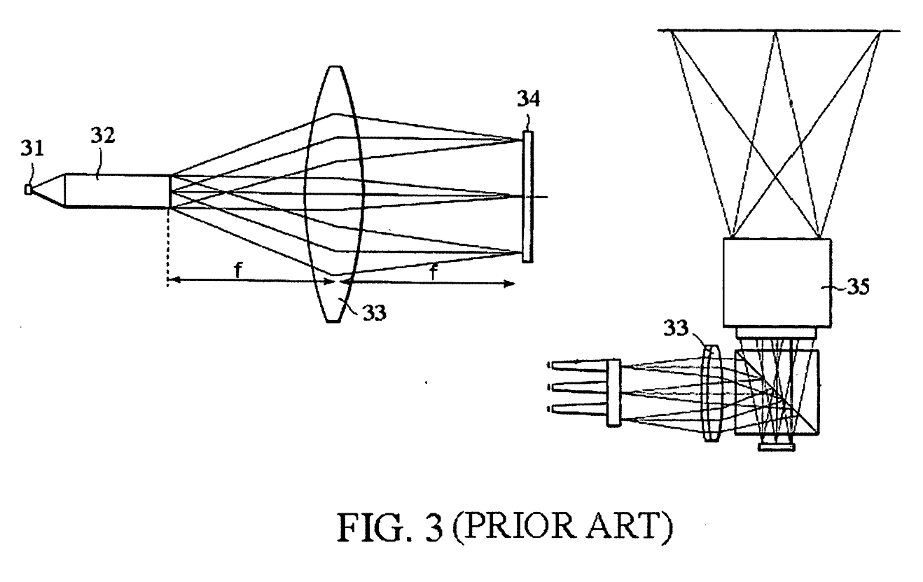

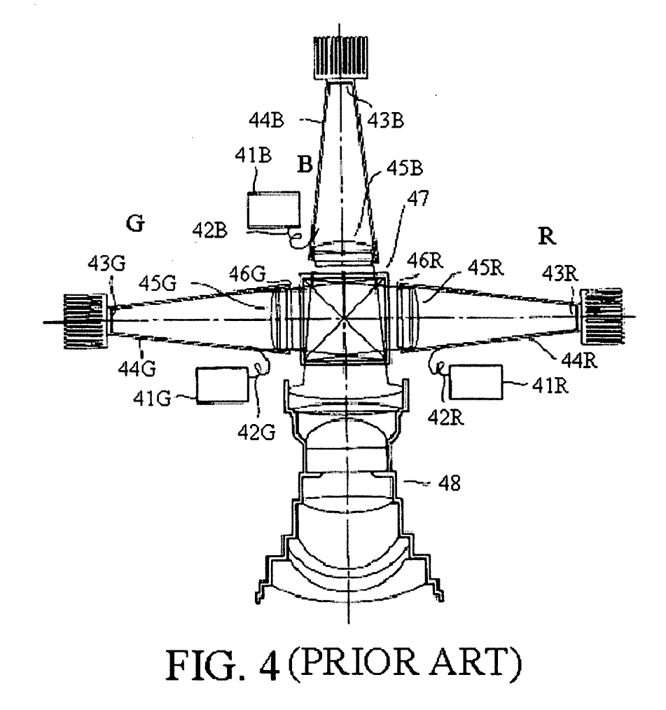

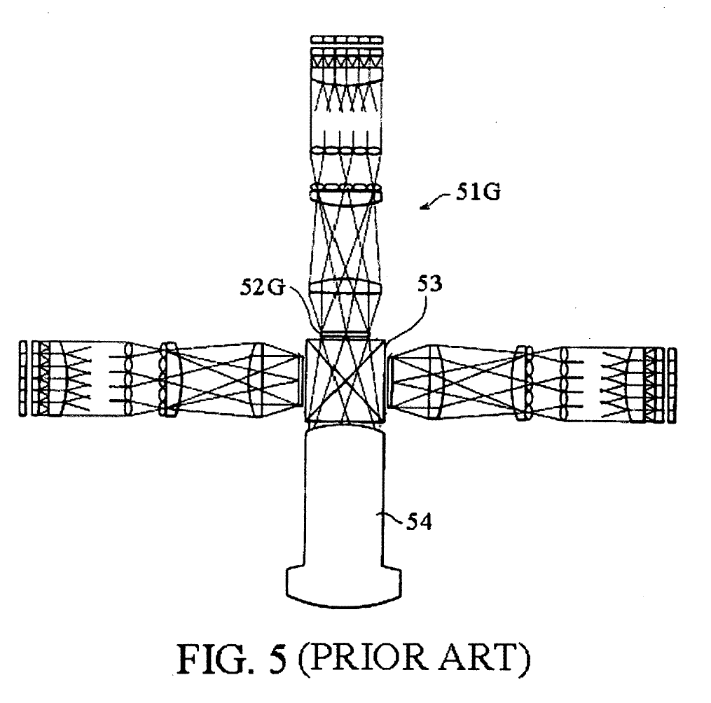

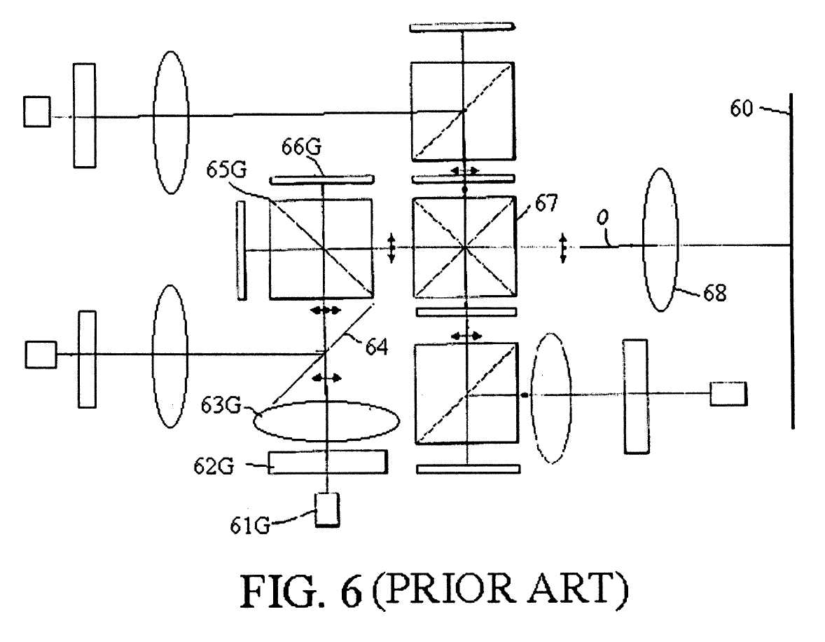

### DETAILED DESCRIPTION OF PREFERRED EMBODIMENTS OF THE INVENTION

As shown in the drawings for purpose of illustration, the present invention is embodied in several different types of illuminators and light modules and can be applied to video display apparatuses and other applications.

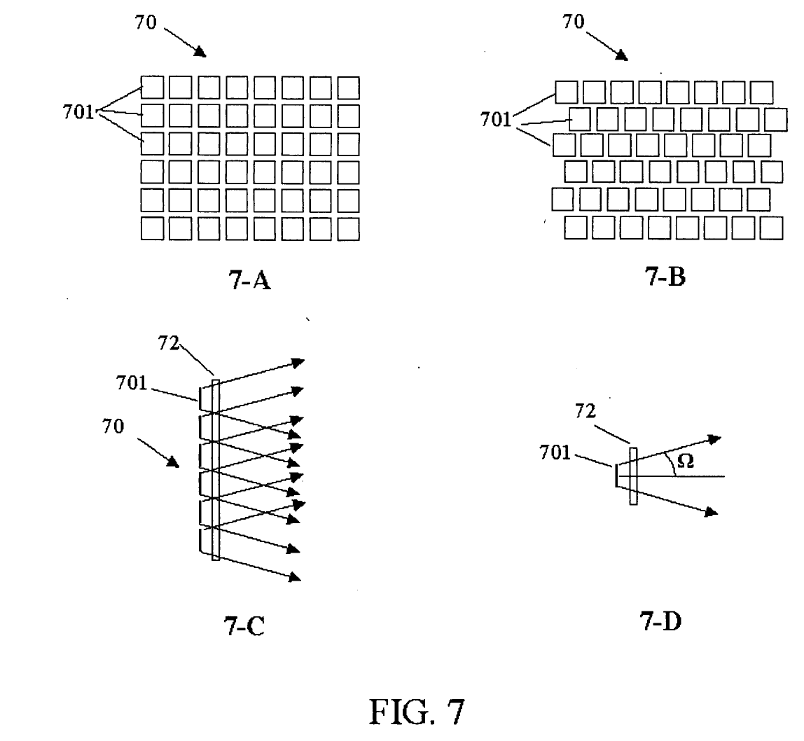

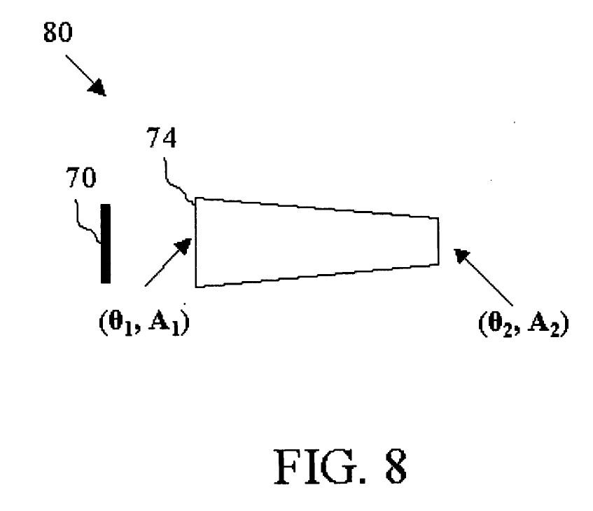

The present invention illustrates different kinds of illuminators. An illuminator comprises at least a light panel and an integrator. The examples of illuminators, marked as illuminator 80, are shown in FIG. 8. FIG. 8 shows an illuminator 80 which comprises a light panel 70 and an integrator 74. The light panel 70 shown in FIG. 7 comprises at least one solid-state lighting unit 701 but commonly comprises a profuse number of solid-state lighting units 701.

The light beams emitted from the solid-state lighting units 701 are more directional than those of conventional LEDs. Therefore, there is no focus, diffusive optical element, and/or external reflection optical element, which collimate or condense the light emitted from the solid-state lighting units 701, between each solid-state lighting unit 701 and the protective transparent cover window 72 of the light panel 70, and that there is no collimating or condensing optical elements existing between the light panel 70 and the integrator 74. Above that, the optical power of light beam emitted from each solid-state lighting unit 701 of the light panel 70 is distributed primarily within a small solid angle Ω less than 15 degrees as shown in FIG. 7-D.

The individual solid-state lighting units 701 can be of the same or different color. There are multiple ways to arrange the solid-state lighting units 701 on the light panel 70 such as an orderly rectangular placement or an off-set placement as illustrated in FIG. 7-A and FIG. 7-B respectively.

The feasible solid-state lighting units 701 in the present invention include Photonic Crystal Light Emitting Diodes (PC-LED), Laser Diodes (LD), Vertical Cavity Surface Emitting Lasers (VCSEL), and other directional solid-state light sources.

The surface of the light panel 70 can be either curved or flat. Additionally, the shape of the light panel 70 is not limited to that of a rectangular shape. The shape of the light panel 70 can resemble various shapes such as a circle, triangle and so forth. The light panel 70 is protected via a transparent cover window 72 as shown in FIG. 7-C the side view of FIG. 7-A.

Since no build in optical elements in the light unit, the pitch size between the units 701 in the array can be as small as possible, and the light panel 701 can be very compact and have highly lumen output. For example, a 10×10 light panel 70, with each individual solid-state lighting unit 701 emits around 5-20 lumens, may has an area of only ˜1 cm² and emits between 500-2000 lumens.

Because the light distribution pattern is un-uniform at long distances, an integrator is used to uniformize the spatial and angular distribution. The taper or the parallel integrators, typically rods, will be called integrator 74 as shown in FIG. 8. There are two basic types of rods of the integrator 74: solid and hollow. The maximum light incident angle and area at the inlet of the rod of the integrator 74 are marked as θ₁ and A₁ respectively as shown in FIG. 8. The maximum light output angle and area at the outlet of the rod of the integrator 74 are marked as θ₂ and A₂ respectively as shown in FIG. 8. In general, the solid angle and the cross-section area of the light having passed through the rod of the integrator 74 can be modulated by the relation of (θ₁, A₁) and (θ₂, A₂) which obeys Etendue conservation principle. Area A₁ can be equal to, less than or greater than area A₂ in the present invention. The shape of inlet and outlet of the rod of the integrator 74 can resemble a circle, hexagon, rectangle, parallelogram or other geometrical shape.

There is no need to dispose any optical element between light panel 70 and the integrator 74. The illuminator 80 has a simple structure that it is not only compact in size and cheap to manufacture, but also offers high luminance and uniformity.

In general, the illuminator 80 of the present invention introduced above can be applied to non-polarization applications. A polarization conversion element (PCE) can be added to the illuminator 80 to the polarization applications.

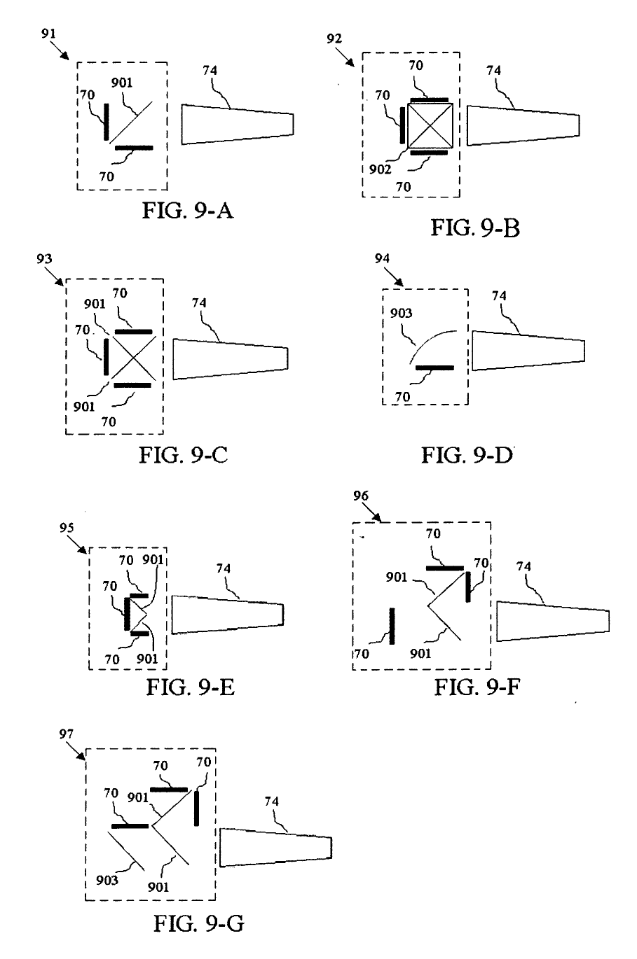

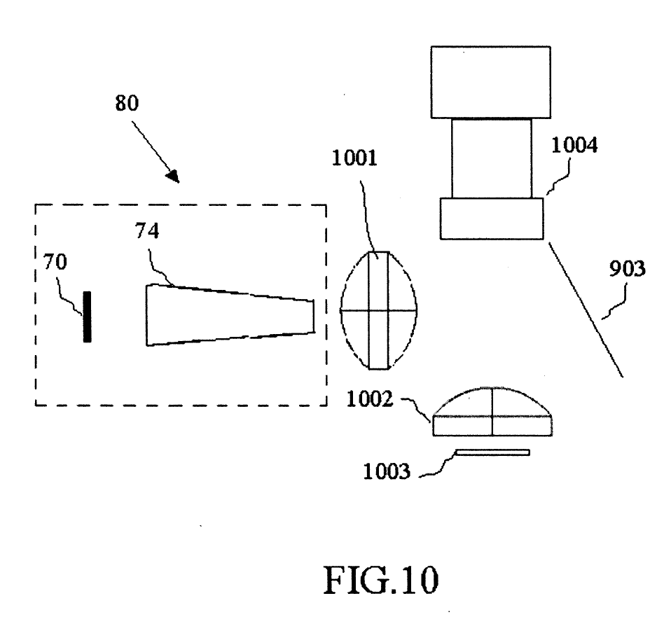

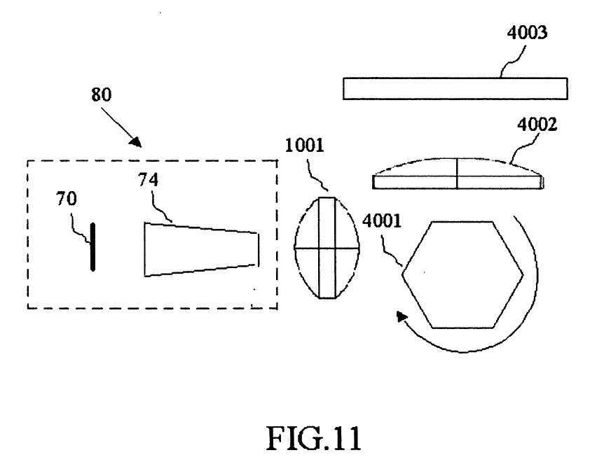

The illuminator 80 introduced above includes only one light panel 70, and has no other element disposed between the light panel 70 and the integrator 74. For convenience, the light panel 70 and other elements disposed before the integrator 74 are collectively called a light module. The light module 90 is defined to have only one light panel as indicated in FIG. 7, FIG. 8, FIG. 10, and FIG. 11. For some applications, it is desirable to combine optical outputs from several light panels 70 into a single light beam before the light beam is incident to the integrator 74. By doing so, the power or color gamut entering the integrator can be increased or expanded respectively. According to embodiments of the present invention, several types of light modules are illustrated in FIG. 9-A to 9-G. The light module 91 comprises two light panels 70 and a dichroic mirror 901 as shown in FIG. 9-A. The light module 92 comprises three light panels 70 and an X-cube prism 902 as shown in FIG. 9-B. The light module 93 comprises three light panels 70 and two dichroic mirrors 901 as shown in FIG. 9-C. The light module 94 comprises a light panel 70 and a reflection mirror 903 as shown in FIG. 9-D. The light module 95 comprises three light panels 70 and two dichroic mirrors 901 as shown in FIG. 9-E. The light module 96 comprises three light panels 70 and two dichroic mirrors 901 as shown in FIG. 9-F. The light module 97 comprises three light panels 70 and two dichroic mirrors 901 and a reflection mirror 903 as shown in FIG. 9-G.

In summary, we can incorporate different light modules 90 into the illuminator 80 for different applications and products according to the need of variant markets and customers. Described below are some examples of applications to which the illuminator of the present invention can be applied.

The other optical element such as an illuminating lens, a reflection mirror, a dichroic mirror, a polarization conversion element (PCE), or other optical lenses and mirrors can be disposed at the outlet of the integrator 74 of the illuminator 80 of the present invention to form another type of light source.

A conventional video display apparatus is composed of a light source, a collimating or condensing optics group, an uniformizing light optics (be typically composed of a couple of fly-eyes lens array or a rod), an illuminating optics group, a color separation and combination optics group (color optics group), one or multiple SLMs and a projection lens.

In the video display apparatus of the present invention, the collimating or condensing optics group, between each solid-state lighting unit 701 and the protective transparent cover window 72, or between the light panel 70 and the integrator 74, is not needed and can be eliminated. In general, all illuminators 80 and light modules introduced above can be applied to the video display apparatus described below. For convenience, we use the light module 90 as a representative for all the light modules in the following embodiments of the video display apparatus shown in FIG. 10. The illuminator of the present invention can be applied to one or multiple SLMs-based (spatial light modulator) video display apparatus.

According to an embodiment of the present invention, a portion of a reflective spatial light modulator (R-SLM) based video display apparatus suitable for a DMD-based or a GLV-based video display apparatus is shown in FIG. 10. A uniform color light beam emitted from the illuminator 80 which comprises a light panel 70, an integrator 74, through an illuminating lens 1001, propagates and is reflected by a reflection mirror 903. It then illuminates onto a SLM illuminating lens [symbol] 1002 and an R-SLM 1003. The R-SLM 1003 modulates the color light beam, the modulated color light beam reflects back to the SLM illuminating lens 1002, and then passes through a projection lens 1004. In this embodiment, the illuminating lens 1001, the reflection mirror 903 and the SLM illuminating lens 1002 collectively form a kind of color optics group.

The R-SLM can be a digital micro-mirror device (DMD) panel, a grating light valve (GLV) panel or a liquid crystal on silicon (LCOS) panel. The apparatus shown in FIG. 10 is suitable for a DMD-based or a GLV-based video display apparatus.

When a liquid crystal on silicon (LCOS) panel is used in the R-SLM based video display apparatus, a polarizer should be disposed between SLM illuminating lens 1002 and R-SLM 1003 to get better contrast in the projection image.

Furthermore, the illuminators of the present invention can apply to a printer, a scanner, a copy machine, an electro-optical modulator (EOM) or an acousto-optical modulator (AOM). FIG. 11 shows a schematic view of a portion of a printer, a scanner or a copy machine, which comprises an illuminator 80, an illuminating lens 1001, a rotating polygon mirror 4001, a scanning lens 4002 and a photoconductor 4003. The illuminator 80 comprises a light panel 70, an integrator 74. The rotating polygon mirror 4001 can be replaced by a rotating mirror or other scanning modulators. The uniform color light beam emitted from the illuminator 80, passing through an illuminating lens 1001, is incident to a rotating polygon mirror 4001, and the light will scan and illuminate on a scanning lens 4002. It will then transmit to a photoconductor 4003 from left to right since the rotating polygon mirror 4001 is repeatedly rotates back and forth. The photoconductor 4003 receives the uniform scanning single or multiple color light beams form the scanning lens 4002 to form a latent image. The illuminator 80 of the present invention can be applied to an AOM or an EOM based system. The uniform light beam emitted from the illuminator 80, passing through an illuminating lens 1001, is incident to an AOM or an EOM. The AOM or EOM modulates the light which can be direct to other lens systems. It can be used in applications which see fast switched circumstances, such as in chemical, physical, and biological process studies, fiber communications, 3D displays, high resolution microscopy, spectrometers and similar applications.

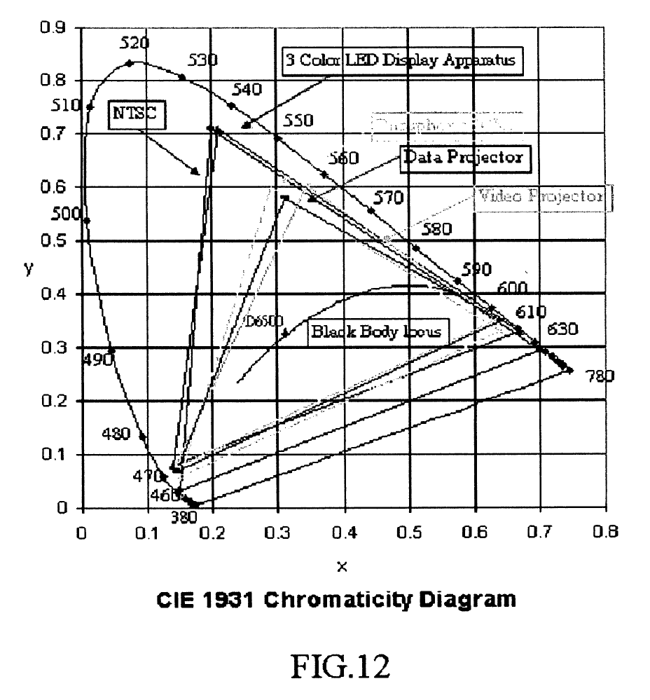

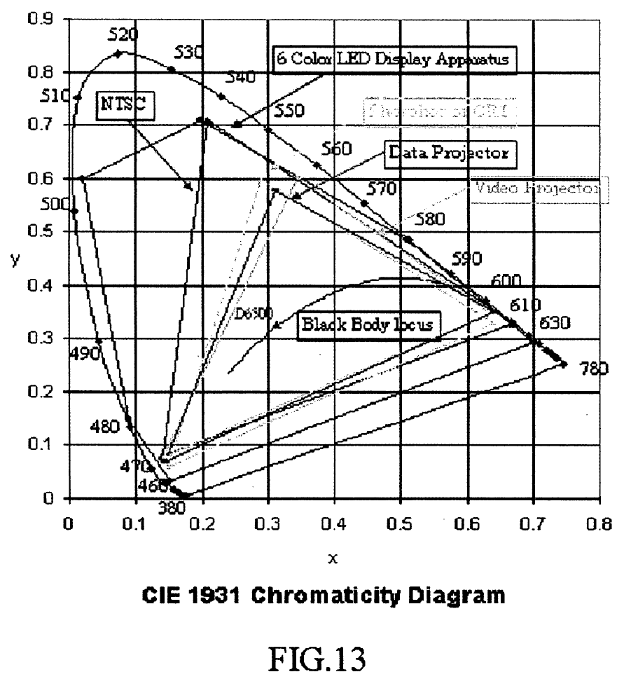

FIG. 12 compares the color gamut of a three principal color wavelength solid-state light source to which the present invention is applied and compares it to the color gamut of National Television Standards Committee (NTSC), cathode ray tube television (CRT TV), a conventional data projector and a video projector. For the purpose of increasing system brightness, a conventional DMD-based data projector always increases the white segment on the color wheel which in turn makes a yellow image look greenish-yellow. The color performance is in turn decreased in the yellow range and some neighboring color gamut. Therefore, yellow is always lacking in a typical DMD-based projector or a rear projection television (RPTV). A video projector offers more pure color saturation than a data projector but sacrifices brightness. In FIG. 12 and FIG. 13, the color gamut of a data projector or a video projector is a little less than that of a CRT TV and the video projector has improved yellow color. The NTSC defines a wider color gamut as show in the FIG. 12 and FIG. 13. It is not possible to reach the NTSC standard via phosphor in conventional CRT TV or high intensity discharge lamps such as metal haline lamps or ultra high pressure lamps in video projectors, data projectors, or RPTVs. The solid-state lighting unit-based projector or video display apparatus can solve the small color gamut and yellow deficiency problem as shown in FIG. 12 and FIG. 13. The three saturated color solid-state lighting unit video display apparatus offers a wider color gamut than the NTSC color gamut as shown in FIG. 12. Also shown in FIG. 12 is that the solid-state lighting units offer more saturation in the blue and red color range. In the present invention, it is easy to apply and package even more solid-state lighting unit arrays onto single light module to realize an even more expanded color gamut video display apparatus. A video display apparatus typically uses a red, green and blue color source. An additional fourth principal color solid-state lighting unit on the single light module can be selectively yellow to solve the yellow deficiency problem on a DMD-based projector. More color solid-state lighting unit arrays can be applied and packaged to the light module to realized an even more expanded color gamut. FIG. 13 illustrates the chromaticity diagram of a light module with six color solid-state lighting unit arrays.

In summary, the light module and the illuminator of the present invention introduced above offer a high uniform luminous output. When applying the illuminator to a video display apparatus, the system brightness can be enhanced simply by increasing electric current or by increasing the number of solid-state lighting unit arrays on the light panel. The size of the illuminator is very small and the total system layout can be made compact when the illuminator of the present invention is applied to a video display apparatus. A palm like projector can be realized through the present invention. The expanded large color gamut could be reached through one or multiple light panels' solution. The yellow deficiency problem in a typical DMD-based projector or a rear projection television (RPTV) can be solved through the invention. A vivid video display apparatus can be carried out through the dynamic control of switching different color wavelength solid-state lighting units on and off. The system contrast and a sharp image also can be further improved upon through the synchronization of the light panel, an SLM, and input video signal source from a personal computer, a laptop, gaming system, or some other signal sources. The full true colors, white point balance, and color temperature can also be modified and control dynamically. The lifetime of a solid-state lighting unit is longer and it consumes less power than a high intensity discharge lamp. The manufacturing and maintenance cost for the illuminators of the present invention in video display apparatuses is lower than those of the conventional video display apparatus. Moreover, it becomes possible to realize a mobile projector that is driven by a battery. The mobile projector can be connected to an Internet or wireless equipment, such as a personal digital assistant, a cell phone, a MP3 player, a digital still camera (DSC), a notebook, or it can be applied to an automobile or some other mobile projection applications. When the Internet or wireless equipment is equipped with a camera and is connected to the signal of the mobile projector, the whole systems form a two-way input and output system. A picture can be captured by a camera and sent to the Internet or wireless equipment, or vice versa. In summary, a very compact, low cost and moving two-way dynamic vivid video display apparatus can be realized through the present invention.

Thus, what is provided is a new illuminator of the present invention applied in video display apparatuses or other system for projection of high color reproduction motion-picture images from digital data, wherein an improved color gamut can be obtained, also an ultra-compact, low cost and moving two-way dynamic vivid video display apparatus can be realized through the present invention.

Although the present invention has been disclosed above via the preferred embodiment, it is not intended to limit the scope of the present invention. It is to be appreciated by persons skilled in the art that any equivalent variation and modification without departing from the spirit of the present invention should be included within the scope of the present invention. The scope of the present invention is to be dependent upon the appended claims stated below.

What is claimed is:

1. A light module, functioning as a uniform and highly luminous solid-state light source, comprising:
at least one light panel, wherein each said light panel further includes one or a plurality of solid-state lighting units which are arranged and packaged in said light panel; and
at least one optical element, used to combine optical outputs of light panels to one optical output;
wherein the light beam emitted from each said solid-state lighting unit of each said light panel is distributed primarily within a small solid angle less than 15 degrees, and inside said light unit, there is no collimating or condensing or reflecting optical elements exist.

2. An illuminator, functioning as a uniform and highly luminous solid-state light source, comprising:
at least one light panel, wherein each said light panel further includes one or a plurality of solid-state lighting units which are arranged and packaged in said light panel; and
an integrator, disposed in front of light output of said light panel to uniformize the spatial and angular distribution of the light beam emitted from said light panel;
wherein the light beam emitted from each said solid-state lighting unit of each said light panel is distributed primarily within a small solid angle less than 15 degrees, and inside said light unit, there is no collimating or condensing or reflecting optical elements exist, and there is no collimating or condensing optical elements existing between said light panel and said integrator.

3. The light module according to claim 1, wherein said solid-state lighting units can be of one or more colors.

4. The light module according to claim 1, wherein the surface of said light panel can be curved or flat.

5. The light module according to claim 1, wherein the shape of said light panel is not limited to that of being a rectangular shape, and can resemble various shapes including circle, triangle and so forth.

6. The light module according to claim 1, wherein said light panel is protected via a transparent cover window.

7. The light module according to claim 1, wherein said light module possesses two light panels and further comprises a dichroic mirror.

8. The light module according to claim 1, wherein said light module possesses three light panels and further comprises an X-cube prism or two dichroic mirrors.

9. The light module according to claim 1, wherein said light module possesses a light panel and further comprises a reflection mirror.

10. The light module according to claim 1, wherein said light module possesses three light panels and further comprises two dichroic mirrors, and a reflection mirror.

11. The light module according to claim 1, further comprising:
an integrator, disposed in front of the light output of said light panel to uniformize the spatial and angular distribution of the light beam emitted from said light panel; and
a polarization conversion element, disposed between said light module and inlet of the said integrator, or disposed at outlet of said integrator to transform all un-polarized light to either p-polarized light or s-polarized light.

12. The illuminator according to claim 2, wherein said solid-state lighting units can be of one or more colors.

13. The illuminator according to claim 2, wherein the surface of said light panel can be curved or flat.

14. The illuminator according to claim 2, wherein the shape of said light panel is not limited to that of being a rectangular shape, and can resemble various shapes including circle, triangle and so forth.

15. The illuminator according to claim 2, wherein said light panel is protected via a transparent cover window.

16. The illuminator according to claim 2, wherein said integrator can be a solid rod or a hollow rod.

17. The illuminator according to claim 2, wherein the shape of inlet and outlet of said integrator is not limited to that of being a rectangular shape, and can resemble various shapes including circle, hexagon, parallelogram, un-equal rectangle, or other geometrical shape.

18. The illuminator according to claim 2, wherein the incident area of said integrator inlet can be larger than, equal to or less than the area of exit.

19. The illuminator according to claim 2, further comprising a polarization conversion element, disposed between said light panel and inlet of said integrator, or disposed at outlet of said integrator to transform all un-polarized light to either p-polarized light or s-polarized light.

20. A video display apparatus, comprising:
at least one light source, providing a uniform un-polarized or polarized single or multiple color light beams and emitting at least three color light beams including a first, second and third color light beams, wherein each of said light sources further includes an illuminator which still further comprises: at least one light panel, comprising at least one highly directive solid-state lighting unit arranged and packaged on said light panel and an integrator, disposed in front of light output of said light panel to uniformize the spatial and angular distribution of the light beam emitted from said light panel;
a color optics group, disposed at outlet of said illuminator, and further including mirrors and lenses, and functioning to separate and direct the light beams emitted from said illuminator;
at least one spatial light modulator, disposed between said color optics group and a projection lens, wherein the uniform light beams coming from said color optics group is modulated by said spatial light modulator and said spatial light modulator sends out a modulated uniform light beams to the color optics group, and said color optics group and said spatial light modulator form a color modulator module; and
a projection lens, disposed in front of said color optics group for focusing said modulated uniform light beams from said color modulator module onto a screen in response to on/off switch of pixels of the spatial light modulator;
wherein the light beam emitted from each said solid-state lighting unit of each said light panel of said light module is distributed primarily within a small solid angle less than 15 degrees, and inside said light=unit, there is no collimating or condensing or reflecting optical elements exist, and there is no collimating or condensing optical elements existing between said light panel and said integrator.

21. The video display apparatus according to claim 20, wherein a light module takes the place of said light panel, and said light module comprises at least one said light panel and at least one optical element that is used to combine optical outputs of light panels to one optical output.
